(19) United States
(12) Patent Application Publication
(10) Pub. No.: US 2025/0210496 A1
(43) Pub. Date: Jun. 26, 2025

(54) SEMICONDUCTOR DIE INCLUDING PACKAGE-SIDE CONDUCTIVE PATH

(71) Applicants: Christopher Schaef, Hillsboro, OR (US); Srikrishnan Venkataraman, Bangalore (IN); Alexander Kashirin, Portland, OR (US)

(72) Inventors: Christopher Schaef, Hillsboro, OR (US); Srikrishnan Venkataraman, Bangalore (IN); Alexander Kashirin, Portland, OR (US)

(21) Appl. No.: 18/394,968

(22) Filed: Dec. 22, 2023

(51) Int. Cl. H01L 23/498; H01L 23/00; H01L 25/065

(52) U.S. Cl. CPC H01L 23/49838; H01L 23/49816; H01L 24/16; H01L 24/48; H01L 25/0657; H01L 2224/16055; H01L 2224/16225; H01L 2224/4801; H01L 2224/48145; H01L 2225/0651; H01L 2225/06513; H01L 2924/1427; H01L 2924/1437; H01L 2924/15311

(57) ABSTRACT

Some embodiments include an apparatus having a die including circuitry; a first conductive path located at a first side of the die; a second conductive path located at a second side of the die and coupled to the circuitry; a conductive structure extending between the first and second sides of the die, the conductive structure including a first end coupled to the first conductive path and a second end coupled to the second conductive path; and a conductive bump coupled to the conductive structure through the first conductive path.

### BACKGROUND

Many electronic items (e.g., cellular phones, computers, and internet of things [IoT]) have devices formed from a semiconductor die. The semiconductor die has conductive connections to deliver power to circuitry of the device. Some of these connections can include through-silicon vias (TSVs) in which the TSVs are formed through the silicon material of the semiconductor die. In some conventional die structures, such TSVs can occupy a relatively large area of the semiconductor die, which can lead to large die area overhead and poor power delivery.

### BRIEF DESCRIPTION OF THE DRAWINGS

FIG. 1A shows an apparatus including a side view (e.g., cross-section) of a die and conductive bumps, according to some embodiments described herein.

FIG. 1B shows a top view (e.g., cross-section) of a portion at a side of the die of FIG. 1A, according to some embodiments described herein.

FIG. 1C shows a top view (e.g., cross-section) of a portion at another side of the die of FIG. 1A, according to some embodiments described herein.

FIG. 1D shows the same view of FIG. 1B without some of the circuit elements of FIG. 1B.

FIG. 1E shows the same view of FIG. 1C without some of the circuit elements of FIG. 1C.

FIG. 2 shows a schematic diagram of part of circuitry of a device in the die of FIG. 1A, according to some embodiments described herein.

FIG. 3A shows an apparatus including multiple dies formed in a stack, according to some embodiments described herein.

FIG. 3B shows a top view (e.g., cross-section) of a portion the die of FIG. 3A, according to some embodiments described herein.

FIG. 4 shows an apparatus including multiple dies stacked over a package substrate and a circuit board, according to some embodiments described herein.

FIG. 5 shows an apparatus in the form of a system, according to some embodiments described herein.

FIG. 6 shows a method of forming an apparatus, according to some embodiments described herein.

### DETAILED DESCRIPTION

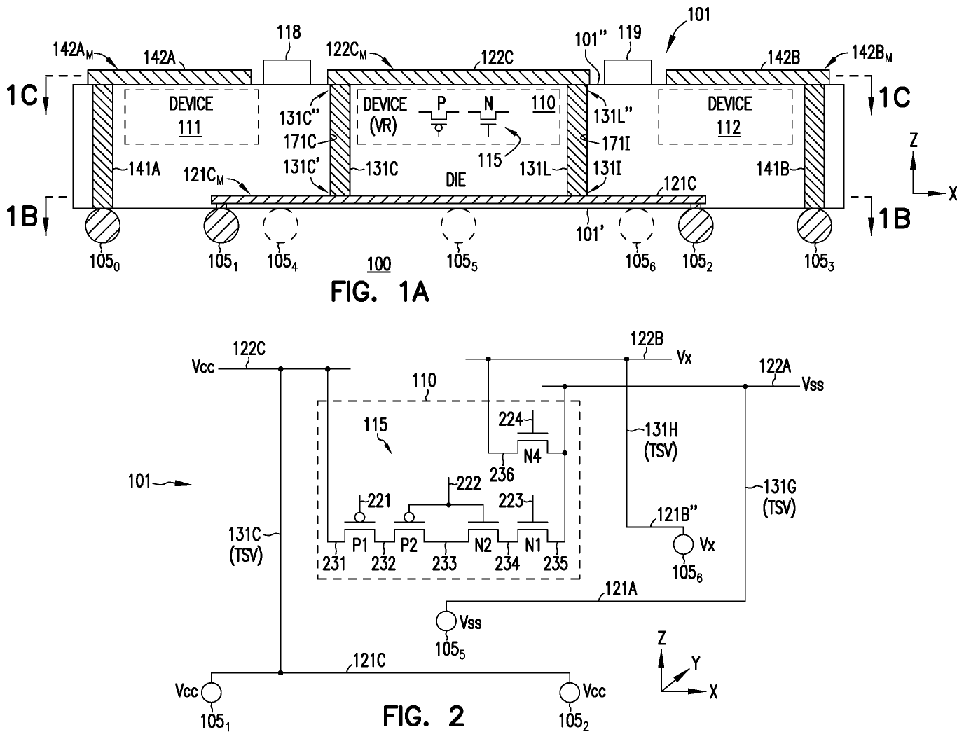

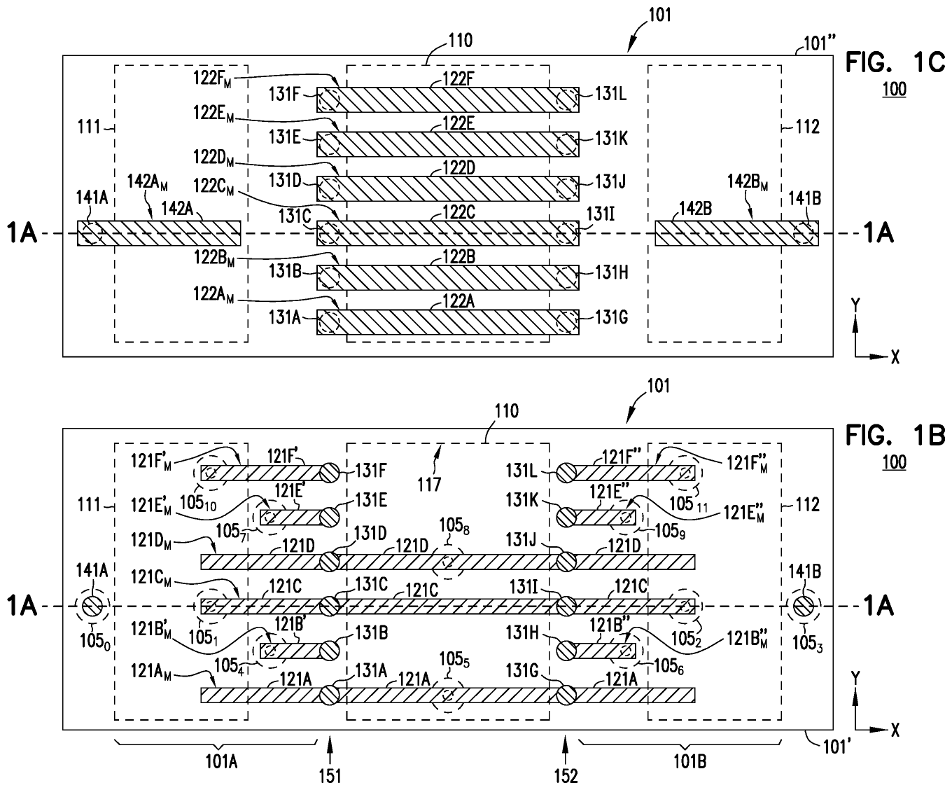

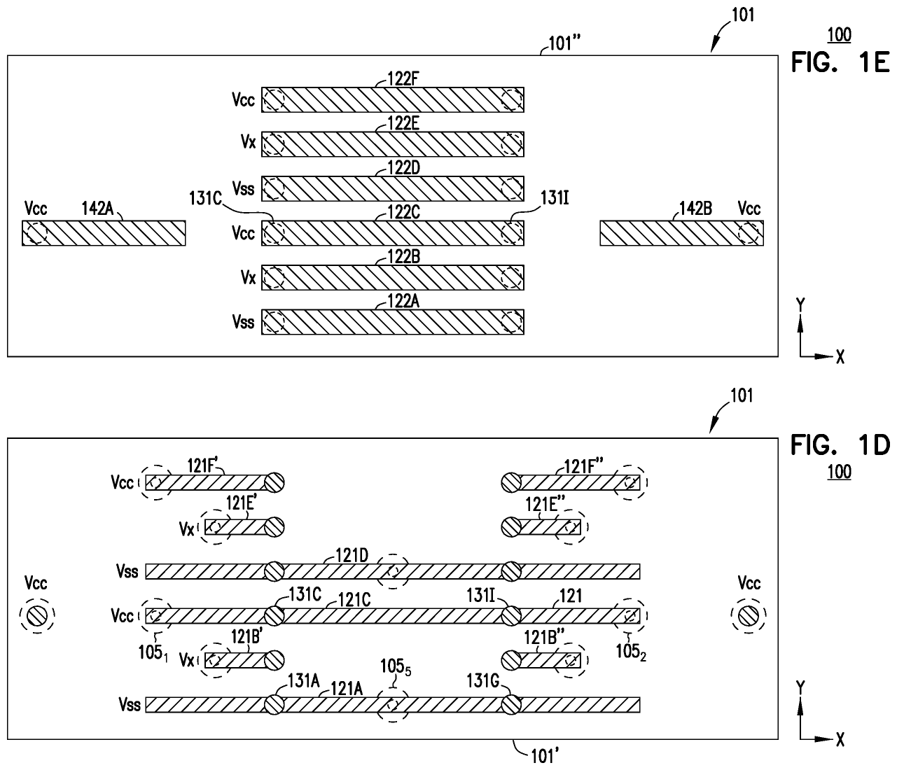

The techniques described herein involve a die (e.g., a semiconductor die) that includes conductive structures (e.g., TSVs) and conductive paths formed to provide conductive connections for power delivery to devices in the die. The techniques described herein also involve an integrated circuit (IC) package that includes multiple dies. The structure of described conductive connections can improve (e.g., reduce) die area overhead and improve power delivery to the multiple dies of the IC package. These and other improvements and benefits of the described techniques are discussed in more detail below with reference to FIG. 1A through FIG. 6.

FIG. 1A shows an apparatus 100 including a side view (e.g., cross-section) of a die 101 and conductive bumps 105₀ through 105₆, according to some embodiments described herein. Die 101 can include or can be included in an integrated circuit (IC) die (e.g., an IC chip, such as a semiconductor chip). Apparatus 100 can include or be included in an electronic device or system, such as a computer (e.g., desktop, laptop, or notebook), a tablet, a cellular phone, a system on chip (SoC), a system in package (SiP), a 3D-chiplet system, or other electronic devices or systems.

In FIG. 1A, die 101 can include a semiconductor die (e.g., silicon-based die). In an example, die 101 can include a non-silicon-based die. Conductive bumps 105₀ through 105₆ can include solder or other conductive materials. Conductive bumps 105₀ through 105₆ can include microbumps or other types of conductive connections. Some or all of conductive bumps 105₀ through 105₆ can be coupled to (e.g., can be part of) power supply connections that can include a positive voltage connection (e.g., to provide voltage Vcc) and ground connection (e.g., to provide voltage Vss) of apparatus 100. Voltage Vcc can be a supply voltage for circuit elements of die 101. For simplicity, FIG. 1 omits additional conductive bumps (which can be similar to conductive bumps 105₀ through 105₆) of apparatus 100. The additional conductive bumps can be used to provide (e.g., carry) additional power supply to apparatus 100 and other information (e.g., data signals) to and from apparatus 100.

A top view (e.g., cross-section) of a portion of die 101 along line 1B-1B is shown in FIG. 1B. A top view (e.g., cross-section) of a portion of die 101 along line 1C-1C is shown in FIG. 1C. FIG. 1A shows a side view (e.g., cross-section) of a die 101 along line 1A-1A in FIG. 1B and FIG. 1C.

For simplicity, cross-section lines (e.g., hatch lines) are omitted from some or all the elements shown in the drawings described herein. Some elements of die 101 (and other dies or devices described herein) may be omitted from a particular figure of the drawings so as not to obscure the view or the description of the element (or elements) being described in that particular figure. Further, the dimensions (e.g., physical structures) of the elements shown in the drawings described herein are not scaled.

As shown in FIG. 1A, die 101 can include devices 110, 111, and 112. Device 110 can include circuitry 115, which can include transistors (e.g., transistors P and N) and other circuit components (not shown). Apparatus 100 can also include circuit elements 118 and 119 that can include any combination of inductors, capacitors, and other circuit elements. For example, each of circuit elements 118 and 119 can include at least one capacitor, at least one inductor, or a combination of at least one capacitor and at least one inductor. In an example, circuit element 118 or circuit element 119 or both circuit elements 118 and 119 can be part of a voltage regulator (VR) of apparatus 100. For example, circuit element 118 or circuit element 119 or both circuit elements 118 and 119 can be part of circuitry 115. FIG. 1A shows an example where circuit elements 118 and 119 are located outside circuitry 115. However, circuit element 118 or circuit element 119 or both circuit elements 118 and 119 can be located (e.g., can be part of) in circuitry 115.

Circuitry 115 of device 110 can include or can be part of the VR of apparatus 100. The VR (e.g., included in circuitry 115) can operate to regulate power provided of one or more of devices 110, 111, and 112 or other devices of apparatus 100. The VR can include Fully Integrated Voltage Regulators (FIVR) or other types of voltage regulators.

Devices 111 and 112 can include memory devices (e.g., static random-access memory SRAM) or other types of devices. As shown in FIG. 1A, devices 110, 111, and 112 can be located side-by-side in the X-direction.

As shown in FIG. 1A, die 101 can include a side (e.g., a bottom portion) 101′ and a side (e.g., a top portion) 101″. Sides 101′ and 101″ are opposite from each other in a Z-direction (e.g., vertical direction), which is perpendicular to the X-direction.

As shown in FIG. 1A, die 101 can include a conductive path 121C located at (e.g., located on) side 101′. Conductive path 121C can be coupled to (in electrical contact with) circuitry 115 (schematically shown in FIG. 2, described below). As shown in FIG. 1A, conductive path 121C can extend (e.g., can have a length) in the X-direction (e.g., a lateral direction perpendicular to the Z-direction). Conductive path 121C can include metal (e.g., copper) or other conductive materials. Conductive path 121C can include or can be part of a metal layer 121 CM, which can be formed in or formed on die 101.

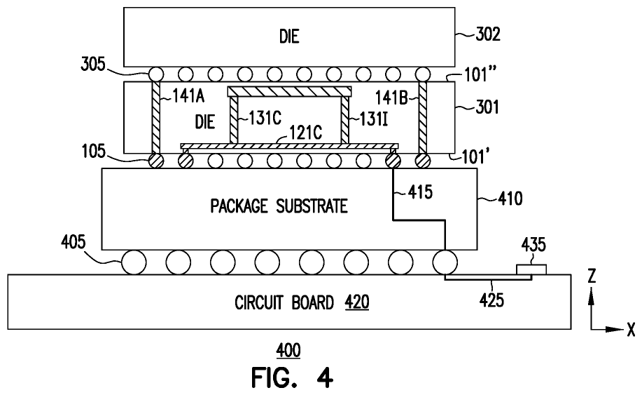

Die 101 can include a conductive path 122C located at (e.g., located on) side 101″. Conductive path 122C can be coupled to (in electrical contact with) circuitry 115 (schematically shown in FIG. 2, described below). As shown in FIG. 1A, conductive path 122C can extend (e.g., can have a length) in the X-direction (e.g., a lateral direction perpendicular to the Z-direction). Conductive path 122C can include metal (e.g., copper) or other conductive material. Conductive path 122C can include or can be part of a metal layer 122 CM, which can be formed in or formed on die 101. As shown in FIG. 1A, conductive paths 121C and 122C are opposite from each other in the Z-direction and can have length in the same direction (e.g., X-direction). In an example (e.g., in FIG. 4), side 101′ can be adjacent a package substrate (e.g., package substrate 410 in FIG. 4) of an apparatus (e.g., a SiP). In such an apparatus, conductive path 121C can be called package-side conductive path (or package-side metal layer).

Die 101 can include conductive structures 131C and 131I. Each of conductive structures 131C and 131I can extend (e.g., can have a length) between sides 101′ and 101″ (e.g., extend vertically in the Z-direction). Conductive structures 131C and 131I can include respective holes 171C and 171I in die 101 and a conductive material (or conductive materials) located inside (e.g., filling) holes 171C and 171I holes. Each of holes 171C and 171I can partially or completely go through die 101. In an example, conductive structure 131C can include a through-silicon via (TSV), such that hole 171C can be part of the TSV of conductive structure 131C. In an example, conductive structure 131C can include a TSV, such that hole 171I can be part of the TSV of conductive structure 131I.

As shown in FIG. 1A, conductive structure 131C can include an end 131C′ (adjacent side 101′) coupled to conductive path 121C, and an end 131C″ (adjacent side 101″) coupled to conductive path 122C. Conductive structure 131I can include an end 131I′ (adjacent side 101′) coupled to conductive path 121C, and an end 131I″ (adjacent side 101″) coupled to conductive path 122C.

As shown in FIG. 1A, conductive bump 105₁ can be coupled to (in electrical contact with) conductive structure (e.g., TSV) 131C (or conductive structure (e.g., TSV) 131I) through conductive path 121C. Conductive bump 105₂can be coupled to conductive structure 131I (or conductive structure 131C) through conductive path 121C. Thus, as shown in FIG. 1A, conductive structure (e.g., TSV) 131C may not be aligned with (e.g., may not be directly over) conductive bump 105₁. Conductive structure (e.g., TSV) 131I may not be aligned with (e.g., may not be formed directly over) conductive bump 105₂.

Die 101 can include conductive structures 141A and 141B coupled to conductive bumps 105₀ and 105₃, respectively. Conductive structures 141A and 141B can be similar to (or the same as) conductive structures 131C and 131I. For example, conductive structures 141A and 141B can include respective TSVs extending in the Z-direction between sides 101′ and 101″. However, as shown in FIG. 1A, unlike the connections between conductive structures 141A and 141B respective conductive bumps 105₁ and 105₂, each of conductive structure 141A and 141B is coupled to a respective conductive bump without going through a conductive path (e.g., conductive path like conductive path 121C) at side 101′ of die 101. For example, conductive structure (e.g., TSV) 141A can be coupled to (e.g., directly coupled to) conductive bump 105₀ without going through a conductive path at side 101′ of die 101. In another example, conductive structure (e.g., TSV) 141B can be coupled to (e.g., directly coupled to) conductive bump 105₃ without going through a conductive path (e.g., like conductive path 121C) at side 101″ of die 101. In these examples (as shown in FIG. 1A), conductive structures 141A and 141B can be aligned with (e.g., can be formed directly over) conductive bump 105₀ and 105₃, respectively.

As shown in FIG. 1A, die 101 can include conductive paths 142A and 142B that are located at (e.g., located on) side 101″ of die 101. Conductive paths 142A and 142B can be coupled to conductive bumps 105₀ and 105₃, respectively, through conductive structures 141A and 141B, respectively. Each of conductive paths 142A and 142B can extend (e.g., can have a length) in the X-direction (e.g., a lateral direction perpendicular to the Z-direction). Conductive paths 142A and 142B can include metal (e.g., copper) or other conductive materials. Conductive paths 142A and 142B can include or can be part of metal layers 141A_{M} and 142B_{M}, respectively.

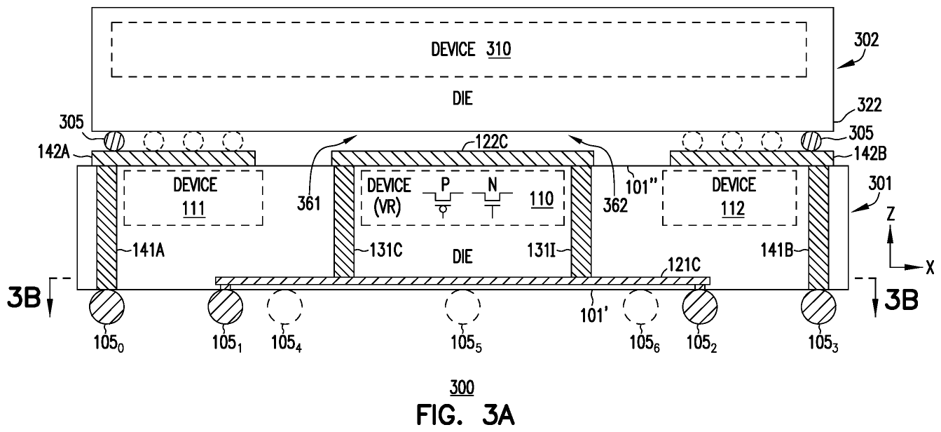

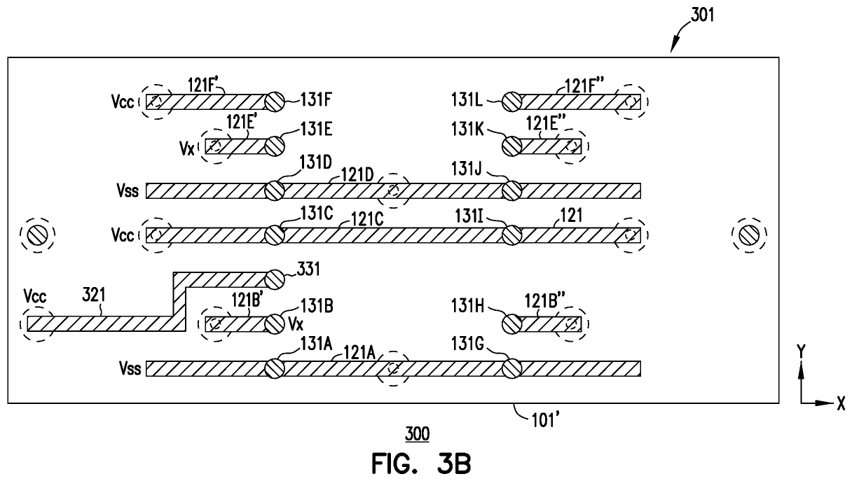

Conductive paths 142A and 142B can be coupled to (in electrical contact with) circuitry (not shown) in one more of devices 110, 111, and 112. Alternatively (or additionally), conductive paths 142A and 142B can be coupled to (in electrical contact with) circuitry in an additional device (not shown) of apparatus 100. Such an additional device can be similar to or the same as device 310 of apparatus 300 (FIG. 3A).

FIG. 1B shows a top view (e.g., cross-section) of a portion of die 101 at (or near) side 101′ along line 1B-1B of FIG. 1A, according to some embodiments described herein. FIG. 1B shows some elements die 101 that are not shown in FIG. Attorney Docket No. 1884.N94US1 6 Client Ref. No. AF6481-US 1A. For example, as shown in FIG. 1B, die 101 can include conductive paths 121A, 121B′, 121B″, 121D, 121C, 121E′, 121E″, 121F′, and 121F″ that can include (or can be part of) metal layers 121A_{M}, 121B′_{M}, 121B″_{M}, 121C_{M}, 121D_{M}, 121E′_{M}, 121E″_{M}, 121F′_{M}, and 121F″_{M}, respectively.

As shown in FIG. 1B, conductive paths 121A, 121B′, 121B″, 121D, 121E′, 121E″, 121F′, and 121F″ can be located on the same plan (e.g., X-Y plan in FIG. 1B) and the same level (in the Z-direction in FIG. 1A) as conductive path 121C. In an example (e.g., in FIG. 4), side 101′ can be adjacent a package substrate (e.g., package substrate 410 in FIG. 4) of an apparatus (e.g., a SiP). In such an apparatus, conductive paths 121A, 121B′, 121B″, 121D, 121E′, 121E″, 121F′, and 121F″ can be called package-side conductive path (or package-side metal layers).

As shown in FIG. 1B, die 101 can include conductive structures (e.g., TSVs shown in top view) 131A through 131L in which side views (e.g., cross-section in the X-Z direction) of conductive structures 131C and 131I are shown in FIG. 1A. Conductive structures (e.g., TSV) 131A through 131L can have similar (or the same) structure. For example, like conductive structures 131C and 131I in FIG. 1A, each of the other conductive structures (among conductive structures 131A through 131L) can extend in the Z-direction (between sides 101′ and 101″ in FIG. 1A) and can include a hole and a conductive material inside the hole. As shown in FIG. 1B, each of conductive structures (e.g., TSVs) 131A through 131L can be coupled to a respective conductive path among conductive paths 121A, 121B′, 121B″, 121C, 121D, 121E′, 121E″, 121F′, and 121F″.

As shown in FIG. 1B, apparatus 100 can include conductive bumps 105₇ through 105₁₁ (located underneath side 101′ of die 101). Conductive bumps 105₀ through 105₁₁ can have similar or the same structure. As shown in FIG. 1B, conductive bumps 105₀ through 105₁₁ can be coupled to (in electrical contact with) respective conductive structures (e.g., TVSs) 131A through 131L through a respective conductive path 121A, 121B′, 121B″, 121C, 121D, 121E′, 121E″, 121F′, and 121F″

As shown in FIG. 1B, conductive structures 131A through 131F can form a row 151 of conductive structures (e.g., a row of TSVs in the Y-direction) adjacent device 110 and between devices 110 and 112. Conductive structures 131G through 131L can form a row 152 of conductive structures (e.g., a row of TSVs in the Y-direction) adjacent device 110 and between devices 110 and 112.

FIG. 1B shows an example where each of conductive structures (e.g., TSV) 131A through 131L is a single conductive structure formed at the location of a respective conductive structure. However, in an alternative structure, die 101 can include many arrays of conductive structures (e.g., an array of TSVs) formed at respective locations of conductive structures 131A through 131L. For example, instead of a single conductive structure 131A, die 101 can include an array of conductive structures (e.g., an array of TSVs) formed at the location of conductive structure 131A. In another example, instead of a single conductive structure 131G, die 101 can include an array of conductive structures (e.g., an array of TSVs) formed at the location of conductive structure 131G. In another example, instead of a single conductive structure 131B, die 101 can include an array of conductive structures (e.g., an array of TSVs) formed at the location of conductive structure 131B. Thus, an alternative structure of die 101 can include rows (e.g., rows 151 and 152) of arrays of conductive structures on opposite sides (sides in the X-direction in FIG. 1B) of device 110 of die 101.

FIG. 1B shows a footprint 117 (dashed line in the X-Y direction) of device 110. Footprint 117 can correspond to the perimeter (e.g., a layout) of device 110 in the X-Y direction. As shown in FIG. 1B, conductive structures (e.g., TVSs) 131A through 131L can be located (formed) outside footprint 117. For example, a portion of conductive structures (e.g., conductive structures 131A through 131F in row 151) can be located (e.g., formed) outside footprint 117 and adjacent device 110 and between devices 110 and 111.

In another example, another portion of conductive structures (e.g., conductive structures 131G through 131L in row 152) can be located (e.g., formed) outside footprint 117 and adjacent device 110. Thus, as shown in FIG. 1B, die 101 may not include a conductive structure (e.g., like conductive structures (e.g., TSVs) 131A through 131L) inside footprint 117 in the X-Y direction (e.g., under device 110 in the Z-direction in FIG. 1A).

As shown in FIG. 1B, die 101 includes areas 101A and 101B. The inclusion of conductive paths 121A, 121B′, 121B″, 121C, 121D, 121E′, 121E″, 121F′, and 121F″ allow the conductive structures (e.g., TSVs) of die 101 to be formed in rows 151 and 152 adjacent device 110 and not formed in areas 101A and 101B. This can improve die area overhead associated with formation of the conductive structures. For example, as shown in FIG. 1B, since the conductive structures are not formed in areas 101A and 101B, these areas (101A and 101B) can be saved for other components (e.g., circuit elements 118 and 119 and device 111 and 112) of die 101. This can result in cost saving. This can also lead to an increase in inductor and capacitor capacity (e.g., increase in the number of circuit elements 118 and 119), resulting in improved performance.

FIG. 1C shows a top view (e.g., cross-section) of a portion of die 101 at (or near) side 101″ along line 1C-1C of FIG. 1A, according to some embodiments described herein. FIG. 1C shows some elements die 101 that are not shown in FIG. 1A. For example, as shown in FIG. 1C, die 101 can include conductive paths 122A, 122B, 122D, 122C, 122E, 122F that can include (or can be part of) metal layers 122A_{M}, 122B_{M}, 122C_{M}, 122D_{M}, 122E_{M}, and 122F_{M}, respectively.

As shown in FIG. 1C, conductive paths 122A, 122B, 122C, 122D, 122E, 122F can be located on the same plane (e.g., X-Y plane in FIG. 1C) and the same level (in the Z-direction in FIG. 1A) as conductive path 122C.

In FIG. 1C conductive structures (e.g., TSVs shown in top view) 131A through 131L are the same as those shown in FIG. 1B. As shown in FIG. 1C, conductive structures 131A through 131L can be coupled to and located underneath respected conductive paths 122A through 122F.

In FIG. 1C, conductive structures (e.g., TSVs shown in top view) 141A and 141B are the same as those shown in FIG. 1A. As shown in FIG. 1C, conductive structures 141A through 141B can be coupled to and located underneath respected conductive paths 142A and 142B.

FIG. 1D and FIG. 1E show the same views as FIG. 1B and FIG. 1C, respectively. However, FIG. 1E and FIG. 1D omit some of the elements that are shown in FIG. 1B and FIG. 1C for purposes of showing power supply connections (associated with voltages Vcc and Vss) and a voltage Vx associated with the conductive paths of apparatus 100. Voltage Vx can be part of a voltage (e.g., switch voltage) at a switching node at an inductor (e.g., circuit element 118 or 119 of FIG. 1A) of a voltage regulator included in circuitry 115 (FIG. 1A).

For simplicity, power supply (e.g., voltages) Vcc and Vss are sometimes called Vcc and Vss (without the term “power supply” (or the “term voltage”)). Similarly, voltage Vx is sometimes called Vx (without the term “voltage”). Vcc and Vx can be part of (e.g., can be coupled to) positive voltage connection and ground connections, respectively, of apparatus 100.

As shown in FIG. 1D and FIG. 1E, Vcc, Vss, and Vx can be associated with (e.g., coupled to) respective conductive paths 121A, 121B′, 121B″, 121C, 121D, 121E′, 121E″, 121F′, and 121F″ (FIG. 1E) and conductive paths 122A through 122F (FIG. 1D). In the description (and the drawings) herein, the elements (e.g., conductive paths, conductive structures (e.g., TSVs), and conductive bumps) that are associated with the same voltage (e.g., Vcc, Vss, or Vx) are electrically in contact with each other. For example, in FIG. 1D, conductive path 121C (located at side 101′) associated with Vcc is in electrical contact with conductive path 122C (located at side 101″ in FIG. E) through conductive structures 131C and 131I extending between sides 101′ and 101″ (FIG. 1D and FIG. 1E). Vcc (part of positive voltage connection) can be provided to die 101 through conductive bumps 105₁ and 105₂ (FIG. 1A) and other connective bumps (not labeled) as shown in FIG. 1D.

In another example, in FIG. 1D, conductive path 121A (located at side 101′ of die 101) associated with Vss is in electrical contact with conductive path 122A (located at side 101″ of die 101) through conductive structures 131A and 131G. Voltage Vss (part of a ground connection) can be provided to die 101 through conductive bumps 105₅ and other connective bumps (not labeled) as shown in FIG. 1D.

FIG. 2 shows a schematic diagram of part of circuitry 115 of device 110 of FIG. 1A, according to some embodiments described herein. In FIG. 2, directions X, Y, and Z can be relative to the physical directions (e.g., dimensions) of the structure of die 101 (FIG. 1A, FIG. 1C, and FIG. 1C). As shown in FIG. 2, circuitry 115 can include transistors (e.g., p-type transistors) P1 and P2 and transistors (e.g., n-type transistors) N1 and N2. Transistors P1 P2, N1, N2, N3, and N4 can include respective gates (gate terminals) 221, 222, 223, and 224 respective non-gate terminals (e.g., sources or drains) 231, 232, 233, 234, 235, and 236. Conductive paths 121A, 121C, 122A, 122B, and 122C described above with reference to FIG. 1A, FIG. 1B, and FIG. 1C are schematically shown in FIG. 2 as lines. FIG. 2 also shows schematic diagrams of conductive structures (e.g., TSVs) 131C, 131G, 131H and conductive bumps 105₁, 105₂, 105₅, and 105₆ of FIG. 1A, FIG. 1B, and FIG. 1C.

As shown in FIG. 2, transistors P1, P2, N1, N2, and N3 of circuitry 115 can be coupled to (can be provided with) voltages Vcc and Vss through conductive connections (e.g., conductive routings) shown in FIG. 2. For example, FIG. 2 shows a conductive connection coupled to Vcc that includes non-gate terminal (e.g., source) 231 of transistor P1, conductive path 122C, conductive structure (e.g., TSV) 131C, conductive path 121C, and conductive bump 105₁. In another example, FIG. 2 shows a conductive connection coupled to Vss that includes non-gate terminal (e.g., source) 235 of transistor N1, conductive path 122A, conductive structure (e.g., TSV) 131G, conductive path 121A, and conductive bump 105₅. In another example, FIG. 2 shows a conductive connection coupled to Vx that includes non-gate terminal (e.g., drain) 236 of transistor N3, conductive path 122B, conductive structure (e.g., TSV) 131H, conductive path 121B″, and conductive bump 105₆.

FIG. 3A shows an apparatus 300 including multiple dies 301 and 302 formed in a stack, according to some embodiments described herein. Apparatus 300 includes elements similar to (or the same as) the apparatus 100. For simplicity, similar or the same elements in apparatuses 100 and 300 are given the same reference labels and their descriptions are not repeated. As shown in FIG. 3A, apparatus 300 can include die 302 stacked over die 301 in the Z-direction. Die 301 and 302 can be part of a SoC, a SiP (e.g., 3-D chiplet package) of apparatus 300. Die 301 can be similar to or the same as die 101 of FIG. 1A, FIG. 1B, and FIG. 1C. Device 310 of die 302 can include circuity of a central processing unit (CPU), a graphic processing unit (CPU), or other circuitries.

As shown in FIG. 3A, apparatus 300 can include conductive connections 305, which can include conductive bumps (e.g., microbumps) or other conductive connections. Conductive connections 305 can be coupled to conductive paths 142A and 142B. Conductive connections 305 can also be coupled to other conductive paths (not shown) that are similar to conductive paths 142A and 142B and to other conductive structures (not shown) that are similar to conductive structures (e.g. TSVs) 141A and 141B. Power supply (e.g., Vcc from conductive bumps 105₀ and 105₃) can be provided to device 310 of die 302 through conductive structures (e.g. TSVs) 141A and 141B and conductive paths 142A and 142B, respectively.

FIG. 3B shows a top view (e.g., cross-section) of a portion of die 301 at side 101′ along line 3B-3B of FIG. 1A, according to some embodiments described herein. The portion of die 301 in FIG. 3B is similar to that of the portion of die 101 in FIG. 1B. Differences between FIG. 1B and FIG. 3B include an addition of a conductive path 321 and a conductive structure (e.g., TSV) 331. Conductive structure 331 can be similar to or the same as one of conductive structures 131A through 131L. However, including conductive structure 331 and conductive path 321 in die 301 can provide further improvements and benefits in addition to the improvements and benefits similar to those of apparatus 100. For example, the structure of die 301 (which is similar to die 101) allows additional conductive structures (e.g., TSVs) like conductive structure 331 (FIG. 3B) to be formed. The additional structures (e.g., conductive structure 331) can allow additional power delivery (e.g., through additional feedthrough power TSV) to die 302 at locations like locations 361 and 362 in FIG. 3A. Additional power delivery to die 302 at such locations (e.g., locations 361 and 362 in FIG. 3A) can reduce the cantilever distance, thereby improving IR (current-resistance) drop associated with power delivery to die 302. Improvement in IR drop can result in power saving and increased performance of devices (e.g., device 310) of apparatus 300.

FIG. 4 shows an apparatus 400 including multiple dies 301 and 302 stacked over a package substrate 410 and a circuit board 420, according to some embodiments described herein. Dies 301 and 302 are the same as those of FIG. 3A. Thus, for simplicity, similar or the same elements in apparatuses 300 and 400 are given the same reference labels and their descriptions are not repeated.

Apparatus 400 can include conductive bumps 105, which can correspond to (e.g., can be similar to or the same as) conductive bumps 105₀ through 105₁₁ (FIG. 1B). Apparatus 400 can include conductive connections 305, which can correspond to conductive connections 305 of FIG. 3A.

As shown in FIG. 4, apparatus 400 can include conductive connections 405, which can include conductive balls (or other types of conductive connections). In an example, the conductive balls of conductive connections 405 can be part of a ball grid array (BGA) or other conductive structures of apparatus 400. As shown in FIG. 4, conductive connections 405 can be part of conductive connections between circuit board 420 and package substrate 410. Package substrate 410 can include an organic substrate and can include conductive connections 415 coupled between conductive connections (e.g., conductive balls) 405 and conductive bumps 105. Circuit board 420 can include a printed circuit board (PCB).

As shown in FIG. 4, apparatus 400 can include a connector (e.g., conductive terminals) 435 and a conductive connection (e.g., conductive traces) 425 coupled between connector 435 and conductive connections 405. Connector 435 can be coupled to a power source (e.g., from a battery or other power sources) to receive power (e.g., voltages Vcc and Vss) that can be used as power supply for the components (e.g., die 301 and 302) of apparatus 400.

As shown in FIG. 4, die 301 is located in apparatus 400 such that side 101′of die 301 is adjacent (e.g., next to) package substrate 410 and conductive path 121C (which is located at side 101′) is also adjacent package substrate 410. As shown in FIG. 4, side 101″ of die 301 is adjacent die 302 and not adjacent (not next to) package substrate 410. Apparatus 400 including multiple dies 301 and 302 assembled as shown in FIG. 4 allows apparatus 400 to have improvement and benefits similar to those of apparatus 100 and 300 described above with reference to FIG. 1A through FIG. 3B.

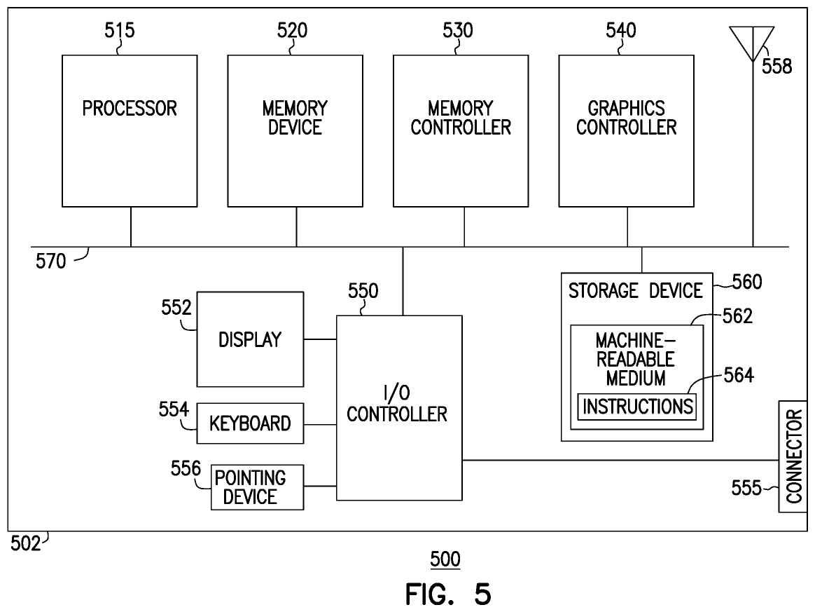

FIG. 5 shows an apparatus in the form of a system (e.g., electronic system) 500, according to some embodiments described herein. System 500 can be viewed as a machine. System (e.g., machine) 500 can include or be included in a computer, a cellular phone, or other electronic systems. As shown in FIG. 5, system 500 can include components (e.g., devices) located on a circuit board (e.g., PCB) 502. The components can include a processor (e.g., a hardware processor) 515, a memory device 520, a memory controller 530, a graphics controller 540, an I/O controller 550, a display 552, a keyboard 554, a pointing device 556, at least one antenna 558, a storage device 560, and a bus 570. Bus 570 can include conductive lines (e.g., metal-based traces on a circuit board 502 where the components of system 500 are located).

System 500 may be configured to perform one or more of the methods and/or operations described herein. At least one of the components of system 500 (e.g., at least one of processor 515, memory device 520, memory controller 530, graphics controller 540, and I/O controller 550) can include at least one of the devices described herein (e.g., devices 110, 111, 112, and 310).

In FIG. 5, processor 515 can include a general-purpose processor or an application specific integrated circuit (ASIC). Processor 515 can include a central processing unit (CPU) and processing circuitry. Graphics controller 540 can include a graphics processing unit (GPU) and processing circuitry. Memory device 520 can include a dynamic random-access memory (DRAM) device, a static random-access memory (SRAM) device, a flash memory device, phase change memory, or a combination of these memory devices, or other types of memory. FIG. 5 shows an example where memory device 520 is a stand-alone memory device separated from processor 515. In an alternative structure, memory device 520 and processor 515 can be located on the same IC chip (e.g., a semiconductor die or IC die). In such an alternative structure, memory device 520 is an embedded memory in processor 515, such as embedded DRAM (eDRAM), embedded SRAM (eSRAM), embedded flash memory, or another type of embedded memory.

Storage device 560 can include a drive unit (e.g., hard disk drive (HHD), solid-state drive (SSD), or another mass storage device). Storage device 560 can include a machine-readable medium 562 and processing circuitry. Machine-readable medium 562 can store one or more sets of data structures or instructions 564 (e.g., software) embodying or used by any one or more of the techniques or functions described herein. Instructions 564 may also reside, completely or at least partially, within memory device 520, memory controller 530, processor 515, or graphics controller 540 during execution thereof by system (e.g., machine) 500.

In an example, one of (or any combination of) processor 515, memory device 520, memory controller 530, graphics controller 540, and storage device 560 may constitute machine-readable media. Non-limiting machine-readable medium examples may include solid-state memories and optical and magnetic media. Specific examples of machine-readable media may include non-volatile memory, such as semiconductor memory devices (e.g., EPROM or EEPROM) and flash memory devices; magnetic disks, such as internal hard disks and removable disks; magneto-optical disks; RAM; and CD-ROM and DVD-ROM disks.

FIG. 5 shows machine-readable medium 562 as a single medium as an example. However, the term “machine-readable medium” may include a single medium or multiple media (e.g., a centralized or distributed database, and/or associated caches and servers) configured to store instructions 564. Further, the term “machine-readable medium” may include any medium that is capable of storing, encoding, or carrying instructions for execution by system 500 and that causes system 500 to perform any one or more of the techniques of the present disclosure, or that is capable of storing, encoding or carrying data structures used by or associated with such instructions. In some examples, machine-readable media may include non-transitory machine-readable media. In some examples, machine-readable media may include machine-readable media that is not a transitory propagating signal.

Display 552 can include a liquid crystal display (LCD), a touchscreen (e.g., capacitive or resistive touchscreen), or another type of display. Pointing device 556 can include a mouse, a stylus, or another type of pointing device. In some structures, system 500 does not have to include a display. Thus, in such structures, display 552 can be omitted from system 500.

Antenna 558 can include one or more directional or omnidirectional antennas, including, for example, dipole antennas, monopole antennas, patch antennas, loop antennas, microstrip antennas, or other types of antennas suitable for transmission of radio frequency (RF) signals. In some structures, system 500 does not have to include an antenna. Thus, in such structures, antenna 558 can be omitted from system 500.

I/O controller 550 can include a communication module for wired or wireless communication (e.g., communication through one or more antennas 558). Such wireless communication may include communication in accordance with WiFi communication technique, Long Term Evolution Advanced (LTE-A) communication technique, or other communication techniques.

I/O controller 550 can also include a module to allow system 500 to communicate with other devices or systems in accordance with to one or more of the following standards or specifications (e.g., I/O standards or specifications), including Universal Serial Bus (USB), DisplayPort (DP), High-Definition Multimedia Interface (HDMI), Thunderbolt, Peripheral Component Interconnect Express (PCIe), Ethernet, and other specifications.

Connector 555 can include terminals (e.g., pins) to allow system 500 to receive a connection (e.g., an electrical connection) from an external device (or system). This may allow system 500 to communicate (e.g., exchange information) with such a device (or system) through connector 555. Connector 555 and at least a portion of bus 570 can include conductive lines that conform with at least one of USB, DP, HDMI, Thunderbolt, PCIe, Ethernet, and other specifications.

FIG. 5 shows the components (e.g., devices) of system 500 arranged separately from each other as an example. For example, each of processor 515, memory device 520, memory controller 530, graphics controller 540, and I/O controller 550 can be included in (e.g., formed in or formed on) a separate integrated circuit (IC) chip (e.g., separate semiconductor die or separate IC die). In some structures of system 500, two or more components (e.g., processor 515, memory device 520, graphics controller 540, and I/O controller 550) of system 500 can be included in (e.g., formed in or formed on) the same IC chip (e.g., same semiconductor die), forming a SoC, or alternatively, a SiP.

The illustrations of the apparatuses (e.g., apparatuses 100, 300, and 400, and system 500) described above are intended to provide a general understanding of the structure of different embodiments and are not intended to provide a complete description of all the elements and features of an apparatus that might make use of the structures described herein.

Any of the components described above with reference to FIG. 1A through FIG. 5 can be implemented in a number of ways, including simulation via software. Thus, apparatuses (e.g., apparatuses 100, 300, and 400, and system 500) may all be characterized as “modules” (or “module”) herein. Such modules may include hardware circuitry, single- and/or multi-processor circuits, memory circuits, software program modules and objects and/or firmware, and combinations thereof, as desired and/or as appropriate for particular implementations of various embodiments. For example, such modules may be included in a system operation simulation package, such as a software electrical signal simulation package, a power usage and ranges simulation package, a capacitance-inductance simulation package, a power/heat dissipation simulation package, a signal transmission-reception simulation package, and/or a combination of software and hardware used to operate or simulate the operation of various potential embodiments.

The apparatuses and methods described above can include or be included in high-speed computers, communication and signal processing circuitry, single- or multi-processor modules, single or multiple embedded processors, multicore processors, message information switches, and application-specific modules including multilayer, multichip modules. Such apparatuses may further be included as subcomponents within a variety of other apparatuses (e.g., electronic systems), such as televisions, cellular telephones, personal computers (e.g., laptop computers, desktop computers, handheld computers, tablet computers, etc.), workstations, radios, video players, audio players (e.g., MP3 (Motion Picture Experts Group, Audio Layer 3) players), vehicles, medical devices (e.g., heart monitor, blood pressure monitor, etc.), set top boxes, and others.

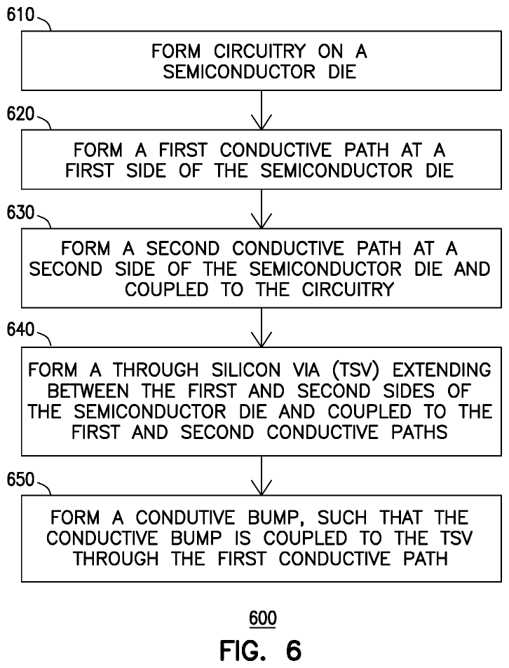

FIG. 6 shows a method 600 of forming an apparatus, according to some embodiments described herein. Method 600 can be used to form at least part of apparatus 100 and 300 and system 500 described above with reference to FIG. 1A through FIG. 5. Method 600 can include activities (e.g., processes) 610, 620, 630, 640, and 650.

As shown in FIG. 6, activity 610 can include forming circuitry (e.g., circuitry 115) on a semiconductor die (e.g., die 101 or die 301). Activity 620 can include forming a first conductive path (e.g., conductive path 121C) located at a first side of the semiconductor die. Activity 630 can include forming a second conductive path (e.g., conductive path 122C) located at a second side of the semiconductor die and coupled to the circuitry. Activity 640 can include forming a TSV extending between the first and second sides of the semiconductor die, such that the TSV is coupled to the first and second conductive paths. Activity 650 can include forming a conductive bump (e.g., conductive bump 105₁ or 105₂), such that the conductive bump is coupled to the TSV through the first conductive path.

Activities 610, 620, 630, 640, and 650 of method 600 can be performed in any order. Method 600 described above can include fewer or more activities relative to activities 610, 620, 630, 640, and 650 shown in FIG. 6. For example, method 600 can include additional activities to form additional components of an apparatus (e.g., apparatus 100, 300, and 400) or system (e.g., system 500) described above with reference to FIG. 1A through FIG. 5. In some embodiments, method 600 can further include activities (e.g., processes) in the examples listed below.

In the detailed description and the claims, the terms “first,” “second,” and “third,” etc. are used merely as labels, and are not intended to impose numerical requirements on their objects.

In the detailed description and the claims, the term “on” used with respect to two or more elements (e.g., materials), one “on” the other, means at least some contact between the elements (e.g., between the materials). The term “over” means the elements (e.g., materials) are in close proximity, but possibly with one or more additional intervening elements (e.g., materials) such that contact is possible but not required. Neither “on” nor “over” implies any directionality as used herein unless stated as such.

In the detailed description and the claims, the term “adjacent” generally refers to a position of a thing being next to (e.g., either immediately next to or close to with one or more things between them) or adjoining another thing (e.g., abutting it or contacting it (e.g., directly coupled to) it).

In the detailed description and the claims, a list of items joined by the term “at least one of” can mean any combination of the listed items. For example, if items A and B are listed, then the phrase “at least one of A and B” means A only; B only; or A and B. In another example, if items A, B, and C are listed, then the phrase “at least one of A, B and C” means A only; B only; C only; A and B (excluding C); A and C (excluding B); B and C (excluding A); or all of A, B, and C. Item A can include a single element or multiple elements. Item B can include a single element or multiple elements. Item C can include a single element or multiple elements.

In the detailed description and the claims, a list of items joined by the term “one of” can mean only one of the list items. For example, if items A and B are listed, then the phrase “one of A and B” means A only (excluding B), or B only (excluding A). In another example, if items A, B, and C are listed, then the phrase “one of A, B and C” means A only; B only; or C only. Item A can include a single element or multiple elements. Item B can include a single element or multiple elements. Item C can include a single element or multiple elements.

Described implementations of the subject matter can include one or more features, alone or in combination as illustrated below by way of examples.

Example 1 is an apparatus comprising a die including circuitry, a first conductive path located at a first side of the die, a second conductive path located at a second side of the die and coupled to the circuitry, a conductive structure extending between the first and second sides of the die, the conductive structure including a first end coupled to the first conductive path and a second end coupled to the second conductive path, and a conductive bump coupled to the conductive structure through the first conductive path.

In Example 2, the subject matter of Example 1 includes subject matter wherein the first conductive path is part of a positive voltage connection for the circuitry.

In Example 3, the subject matter of Example 1 includes subject matter wherein the first conductive path is part of a ground connection for the circuitry.

In Example 4, the subject matter of any of Examples 1-3 includes subject matter wherein the circuitry includes a transistor, the transistor including a non-gate terminal coupled to the first conductive path.

In Example 5, the subject matter of any of Examples 1-4 includes subject matter wherein the first conductive path is formed from metal.

In Example 6, the subject matter of any of Examples 1-5 includes an additional conductive structure extending between the first and second sides of the die, the additional conductive structure including a first end coupled to the first conductive path and a second end coupled to the second conductive path, and wherein the conductive bump is coupled to the additional conductive structure through the first conductive path.

In Example 7, the subject matter of any of Examples 1-5 includes a first additional conductive path located at the first side of the die, a second additional conductive path located at the second side of the die and coupled to the circuitry, an additional conductive structure extending between the first and second sides of the die, the additional conductive structure including a first end coupled to the first additional conductive path and a second end coupled to the second additional conductive path, and an additional conductive bump coupled to the additional conductive structure through the first additional conductive path.

In Example 8, the subject matter of Example 7 includes subject matter wherein the first conductive path is part of a first power supply connection of the circuitry, and the second conductive path is part of a second power supply connection of the circuitry.

In Example 9, the subject matter of any of Examples 1-8 includes subject matter wherein the apparatus comprises a system on chip (SoC), the SoC including the die.

In Example 10, the subject matter of any of Examples 1-9 includes an additional die stacked over the die.

In Example 11, the subject matter of any of Examples 8-10 includes subject matter wherein one of the first and second supply connections is part of a positive voltage connection of the circuitry.

In Example 12, the subject matter of any of Examples 8-11 includes subject matter wherein one of the first and second power supply connections is part of a ground connection of the circuitry.

In Example 13, the subject matter of any of Examples 1-9 includes subject matter wherein the first conductive path is part of a positive voltage connection for the circuitry, and the first conductive path is part of a ground connection for the circuitry.

In Example 14, the subject matter of any of Examples 1-13 includes an inductor at the second side of the die.

In Example 15, the subject matter of any of Examples 1-14 includes a capacitor located at the second side of the die.

In Example 16, the subject matter of any of Examples 1-15 includes subject matter wherein the second conductive path is formed from metal.

In Example 17, the subject matter of any of Examples 1-16 includes subject matter wherein the conductive structure includes a hole and a conductive material located inside the hole.

In Example 18, the subject matter of any of Examples 1-17 includes subject matter wherein the circuitry includes part of a voltage regulator.

Example 19 is an apparatus comprising a semiconductor die including circuitry, a first metal layer located at a first side of the semiconductor die and coupled to the circuitry, a second metal layer located at a second side of the semiconductor die, a through-silicon via (TSV) extending between the first and second sides of the semiconductor die and coupled to the first and second metal layers, a package substrate adjacent the first side of the semiconductor die, and a conductive bump between the package substrate and the first side of the semiconductor die, the conductive bump coupled to the TSV through the first metal layer.

In Example 20, the subject matter of Example 19 includes an additional TSV extending between the first and second sides of the semiconductor die and coupled to the first and second metal layers, and wherein the conductive bump is coupled to the additional TSV through the first metal layer.

In Example 21, the subject matter of any of Examples 19-20 includes a first additional metal layer located at a first side of the semiconductor die, a second additional metal layer located at a second side of the semiconductor die and coupled to the circuitry, an additional TSV extending between the first and second sides of the semiconductor die and coupled to the first additional metal layer, and an additional conductive bump coupled to the additional TSV through the first additional metal layer.

In Example 22, the subject matter of any of Examples 19-21 includes subject matter wherein the first metal layer is part of a positive voltage connection of the circuitry, and the second metal layer is part of a ground connection for the circuitry.

In Example 23, the subject matter of any of Examples 19-22 includes subject matter wherein the circuitry includes a footprint, and the TSV is located outside the footprint.

In Example 24, the subject matter of any of Examples 19-23 includes subject matter wherein the apparatus comprises a system in a package (SiP), the SiP including the semiconductor die.

In Example 25, the subject matter of any of Examples 19-24 includes a connector coupled to the semiconductor die, wherein the connector conforms with at least one of Universal Serial Bus (USB), High-Definition Multimedia Interface (HDMI), Thunderbolt, Peripheral Component Interconnect Express (PCIe), and Ethernet specifications.

In Example 26, the subject matter of any of Examples 19-25 includes an additional semiconductor die, wherein the semiconductor die is located between the additional semiconductor die and the package substrate, an additional metal layer located at the first side of the semiconductor die, an additional TSV extending between the first and second sides of the semiconductor die and coupled to the second additional metal layer and the second semiconductor die, and an additional conductive bump coupled to the additional TSV.

In Example 27, the subject matter of any of Examples 19-26 includes subject matter wherein the first and second metal layers have respective lengths in a same direction.

In Example 28, the subject matter of Example 21 includes subject matter wherein the first metal layer and the first additional metal layer and are located on a same plan.

In Example 29, the subject matter of Example 21 or 28 includes subject matter wherein the second metal layer and the second additional metal layer are located on a same plan.

In Example 30, the subject matter of Example 26 includes subject matter wherein the TVS and the additional TSV are part of a row of TSVs of the semiconductor die.

In Example 31, the subject matter of any of Examples 19-30 includes subject matter wherein the circuitry includes a capacitor.

In Example 32, the subject matter of any of Examples 19-31 includes subject matter wherein the circuitry includes an inductor.

In Example 33, the subject matter of any of Examples 19-31 includes subject matter wherein the circuitry includes a capacitor and an inductor.

In Example 34, the subject matter of any of Examples 19-33 includes subject matter wherein the circuitry includes part of a voltage regulator.

Example 35 is a method comprising forming circuitry on a semiconductor die, forming a first conductive path at a first side of the semiconductor die, forming second conductive path at a second side of the semiconductor die and coupled to the circuitry, forming a through-silicon via (TSV) extending between the first and second sides of the semiconductor die, such that the TSV is coupled to the first and second conductive paths, and forming a conductive bump, such that the conductive bump is coupled to the TSV through the first conductive path.

In Example 36, the subject matter of Example 25 includes forming an additional TSV extending between the first and second sides of the semiconductor die, such that the additional TSV is coupled to the first and second conductive paths and the conductive bump is coupled to the additional TSV through the first conductive path.

In Example 37, the subject matter of any of Examples 35-36 includes subject matter wherein forming the circuitry includes forming part of a voltage regulator of the circuitry.

In Example 38, the subject matter of any of Examples 35-37 includes subject matter wherein the first conductive path is formed from metal.

In Example 39, the subject matter of any of Examples 35-38 includes subject matter wherein the second conductive path is formed from metal.

Example 40 is an apparatus comprising means to implement any of Examples 1-39.

Example 41 is a system to implement any of Examples 1-39.

Example 42 is a method to implement any of Examples 1-39.

The subject matter of Examples 1-42 may be combined in any combination.

The above description and the drawings illustrate some embodiments of the inventive subject matter to enable those skilled in the art to practice the embodiments of the inventive subject matter. Other embodiments may incorporate structural, logical, electrical, process, and other changes. Examples merely typify possible variations. Portions and features of some embodiments may be included in, or substituted for, those of others. Many other embodiments will be apparent to those of skill in the art upon reading and understanding the above description.

The Abstract is provided to allow the reader to ascertain the nature and gist of the technical disclosure. It is submitted with the understanding that it will not be used to limit or interpret the scope or meaning of the claims. The following claims are hereby incorporated into the detailed description, with each claim standing on its own as a separate embodiment.

What is claimed is:

1. An apparatus comprising:
a die including circuitry;
a first conductive path located at a first side of the die;
a second conductive path located at a second side of the die and coupled to the circuitry;
a conductive structure extending between the first and second sides of the die, the conductive structure including a first end coupled to the first conductive path and a second end coupled to the second conductive path; and
a conductive bump coupled to the conductive structure through the first conductive path.

2. The apparatus of claim 1, wherein the first conductive path is part of a positive voltage connection for the circuitry.

3. The apparatus of claim 1, wherein the first conductive path is part of a ground connection for the circuitry.

4. The apparatus of claim 1, wherein the circuitry includes a transistor, the transistor including a non-gate terminal coupled to the first conductive path.

5. The apparatus of claim 1, wherein the first conductive path is formed from metal.

6. The apparatus of claim 1, further comprising:
an additional conductive structure extending between the first and second sides of the die, the additional conductive structure including a first end coupled to the first conductive path and a second end coupled to the second conductive path; and
wherein the conductive bump is coupled to the additional conductive structure through the first conductive path.

7. The apparatus of claim 1, further comprising:
a first additional conductive path located at the first side of the die;
a second additional conductive path located at the second side of the die and coupled to the circuitry;
an additional conductive structure extending between the first and second sides of the die, the additional conductive structure including a first end coupled to the first additional conductive path and a second end coupled to the second additional conductive path; and
an additional conductive bump coupled to the additional conductive structure through the first additional conductive path.

8. The apparatus of claim 7, wherein:
the first conductive path is part of a first power supply connection of the circuitry; and
the second conductive path is part of a second power supply connection of the circuitry.

9. The apparatus of claim 1, wherein the apparatus comprises a system on chip (SoC), the SoC including the die.

10. The apparatus of claim 1, further comprising an additional die stacked over the die.

11. An apparatus comprising:
a semiconductor die including circuitry;
a first metal layer located at a first side of the semiconductor die and coupled to the circuitry;
a second metal layer located at a second side of the semiconductor die;
a through-silicon via (TSV) extending between the first and second sides of the semiconductor die and coupled to the first and second metal layers;
a package substrate adjacent the first side of the semiconductor die; and
a conductive bump between the package substrate and the first side of the semiconductor die, the conductive bump coupled to the TSV through the first metal layer.

12. The apparatus of claim 11, further comprising:
an additional TSV extending between the first and second sides of the semiconductor die and coupled to the first and second metal layers; and
wherein the conductive bump is coupled to the additional TSV through the first metal layer.

13. The apparatus of claim 11, further comprising:
a first additional metal layer located at a first side of the semiconductor die;
a second additional metal layer located at a second side of the semiconductor die and coupled to the circuitry;
an additional TSV extending between the first and second sides of the semiconductor die and coupled to the first additional metal layer; and
an additional conductive bump coupled to the additional TSV through the first additional metal layer.

14. The apparatus of claim 13, wherein:
the first metal layer is part of a positive voltage connection of the circuitry; and
the first metal layer is part of a ground connection for the circuitry.

15. The apparatus of claim 11, wherein the circuitry includes a footprint, and the TSV is located outside the footprint.

16. The apparatus of claim 11, wherein the apparatus comprises a system in a package (SiP), the SiP including the semiconductor die.

17. The apparatus of claim 11, further comprising a connector coupled to the semiconductor die, wherein the connector conforms with at least one of Universal Serial Bus (USB), High-Definition Multimedia Interface (HDMI), Thunderbolt, Peripheral Component Interconnect Express (PCIe), and Ethernet specifications.

18. A method comprising:
forming circuitry on a semiconductor die;
forming a first conductive path at a first side of the semiconductor die;
forming second conductive path at a second side of the semiconductor die and coupled to the circuitry;
forming a through-silicon via (TSV) extending between the first and second sides of the semiconductor die, such that the TSV is coupled to the first and second conductive paths; and
forming a conductive bump, such that the conductive bump is coupled to the TSV through the first conductive path.

19. The method of claim 18, further comprising:
forming an additional TSV extending between the first and second sides of the semiconductor die, such that the additional TSV is coupled to the first and second conductive paths and the conductive bump is coupled to the additional TSV through the first conductive path.

20. The method of claim 18, wherein forming the circuitry includes forming part of a voltage regulator of the circuitry.
